(19) United States
(12) Patent Application Publication
(10) Pub. No.: US 2025/0287706 A1
(43) Pub. Date: Sep. 11, 2025

(54) SPAD STRUCTURE AND MANUFACTURING METHOD THEREOF

(71) Applicant: DB HiTek Co., Ltd., Bucheon-si (KR)

(72) Inventors: Nak Won YU, Bucheon-si (KR); Jong Min KIM, Bucheon-si (KR)

(21) Appl. No.: 18/660,576

(22) Filed: May 10, 2024

(30) Foreign Application Priority Data
Mar. 11, 2024 (KR) 10-2024-0033749

(51) Int. Cl. H01L 31/107; H01L 31/032; H01L 31/0352

(52) U.S. Cl. CPC H10F 30/225; H10F 77/12; H10F 77/14

(57) ABSTRACT

Proposed are a Single Photon Avalanche Diode (SPAD) structure and a manufacturing method thereof. More particularly, the SPAD structure is configured such that a guide wall is formed on side portions of a first impurity doped region and a second impurity doped region so as to induce photogenerated charges to be diffused to an avalanche region on a PN junction region between the first impurity doped region and the second impurity doped region, thereby increasing Photon Detection Efficiency (PDE).

### CROSS-REFERENCE TO RELATED APPLICATION

The present application claims priority to Korean Patent Application No. 10-2024-0033749, filed Mar. 11, 2024, the entire contents of which are incorporated herein for all purposes by this reference.

### BACKGROUND

### Technical Field

The present disclosure relates to a Single Photon Avalanche Diode (SPAD) structure and a manufacturing method of the SPAD structure. More particularly, the present disclosure relates to a SPAD structure and a manufacturing method of the SPAD structure configured such that a guide wall is formed on side portions of a first impurity doped region and a second impurity doped region so as to induce photogenerated charges to be diffused to an avalanche region on a PN junction region between the first impurity doped region and the second impurity doped region, thereby increasing Photon Detection Efficiency (PDE).

### Description of the Related Art

Generally, single-photon avalanche diodes referred to as SPADs are utilized as pixel photoelectric conversion devices of imaging devices. SPADs have PN junctions to detect incident radiation, and may operate in Geiger mode, that is, a mode operating with a voltage much higher than a breakdown voltage, which is also referred to as an avalanche voltage, of a single-photon avalanche diode. Since a voltage exceeding the breakdown voltage is applied to a SPAD, an electron avalanche occurs due to carriers generated by photoelectric conversion, and the SPAD enters a breakdown state. As a result, carrier amplification caused by photoelectric conversion occurs, and the sensitivity in the imaging device may be increased.

FIG. 1 is a cross-sectional view illustrating a conventional SPAD structure.

Referring to FIG. 1, a substrate 910 having a front surface 911 and a rear surface 913 is formed in a conventional SPAD structure 9. In addition, in the substrate 910, a structure in which a P-type region 930 is stacked on an N-type region 950 may be formed. A PN junction region may be formed by the P-type region 930 and the N-type region 950. In the structure 9 described above, when an inverse voltage sufficient to enable avalanche breakdown is applied to the PN junction, electron generated by a single photon reaches an avalanche region A and generates a large current pulse, so that the single photon can be measured. Generally, in the SPAD structure 9, the Photon Detection Efficiency (PDE) is derived from the number of current pulses generated by photogenerated electrons compared to the number of photons reaching a pixel. Therefore, in order to secure a high PDE, the photogenerated electrons is required to reach the avalanche region A as much as possible.

In the existing SPAD structure 9 described above, a significant amount of photogenerated electrons is diffused to a side surface of the PN junction region rather than the avalanche region A, so that there is a problem that the photogenerated electrons diffused to the side surface of the PN junction region are not contributing to the detection of photons. Particularly, electrons generated in side portions of the P-type region 930 and the N-type region 950 do not pass through the avalanche region A, but are introduced into a cathode through the side portion of the PN junction region that is the shortest distance.

In order to solve the problem described above, the inventors of the present disclosure intend to provide a new SPAD pixel structure and a manufacturing method of the SPAD pixel structure that has an improved structure, and a detailed description will be described later.

### DOCUMENT OF RELATED ART

(Patent Document 1) Korean Patent Application Publication No. 10-2019-0049598 ‘SPAD

### SUMMARY OF THE DISCLOSURE

Accordingly, the present disclosure has been made keeping in mind the above problems occurring in the related art, and an objective of the present disclosure is to provide a Single Photon Avalanche Diode (SPAD) structure and a manufacturing method of the SPAD structure configured such that a guide wall is formed on side portions of a first impurity doped region and a second impurity doped region so as to induce photogenerated charges to be diffused to an avalanche region on a PN junction region between the first impurity doped region and the second impurity doped region, thereby increasing Photon Detection Efficiency (PDE).

In addition, another objective of the present disclosure is to provide a Single Photon Avalanche Diode (SPAD) structure and a manufacturing method of the SPAD structure configured such that a gap between a first region and a second region is not formed, thereby preventing photogenerated charges generated in a side portion of a substrate from being diffused to a side portion of a PN junction region.

In addition, still another objective of the present disclosure is to provide a Single Photon Avalanche Diode (SPAD) structure and a manufacturing method of the SPAD structure configured such that a second region is doped with impurities having a low concentration compared to that of a first region, thereby allowing photogenerated charges generated in a side portion of a substrate to be diffused to an avalanche region.

In addition, yet another objective of the present disclosure is to provide a Single Photon Avalanche Diode (SPAD) structure and a manufacturing method of the SPAD structure configured such that a guard ring is formed between a first region and both a first impurity doped region and a second impurity doped region, thereby lowering dark count rate.

In addition, yet another objective of the present disclosure is to provide a Single Photon Avalanche Diode (SPAD) structure and a manufacturing method of the SPAD structure configured such that a second region is formed such that the second region is in contact with a second impurity doped region, thereby allowing photogenerated charges to be diffused to an avalanche region.

In addition, yet another objective of the present disclosure is to provide a Single Photon Avalanche Diode (SPAD) structure and a manufacturing method of the SPAD structure configured such that a second region that is a region doped with impurities having a first conductivity type overlaps a second impurity doped region that is a region doped with impurities having the first conductivity type that has a low concentration compared to that of the second region, thereby preventing the second impurity doped region from being misaligned with a first impurity doped region.

The present disclosure may be implemented by one or more embodiments having some or all of the following configurations, to achieve one or more of the above-described objectives.

According to an embodiment of the present disclosure, there is provided a Single Photon Avalanche Diode (SPAD) structure including: a substrate having a front surface and a rear surface; a first impurity doped region disposed on the front surface of the substrate within the substrate; a second impurity doped region disposed on the first impurity doped region within the substrate; and a guide wall surrounding side walls of the first impurity doped region and the second impurity doped region within the substrate.

According to another embodiment of the present disclosure, the guide wall of the SPAD structure according to the present disclosure may have an impurity doped region having a first conductivity type, and the first impurity doped region may have an impurity doped region having a second conductivity type.

According to still another embodiment of the present disclosure, the guide wall of the SPAD structure according to the present disclosure may include a first region that extends from the front surface of the substrate toward the rear surface of the substrate.

According to yet another embodiment of the present disclosure, within the substrate, the first region of the SPAD structure according to the present disclosure may have a rear surface disposed higher than a rear surface of the second impurity doped region.

According to yet another embodiment of the present disclosure, the guide wall of the SPAD structure according to the present disclosure may further include a second region that extends from a rear surface of the first region toward a rear surface of the second impurity doped region adjacent to the second region.

According to yet another embodiment of the present disclosure, the second region of the SPAD structure according to the present disclosure may be in contact with the second impurity doped region.

According to yet another embodiment of the present disclosure, the second region may have an opening so that the rear surface of the second impurity doped region is at least partially open.

According to yet another embodiment of the present disclosure, the second region of the SPAD structure according to the present disclosure may have impurities having the first conductivity type that has a lower concentration compared to a concentration of impurities having the first conductivity type of the first region.

According to yet another embodiment of the present disclosure, the SPAD structure according to the present disclosure may further include: a first contact region disposed within the first impurity doped region on the front surface of the substrate; and a second contact region disposed apart from the first contact region on the front surface of the substrate within the substrate.

According to yet another embodiment of the present disclosure, the SPAD structure according to the present disclosure may further include a guard ring disposed between the guide wall and both the first impurity doped region and the second impurity doped region that are adjacent to the guide wall.

According to yet another embodiment of the present disclosure, the guard ring of the SPAD structure according to the present disclosure may have impurities having the first conductivity type that has a lower concentration compared to concentrations of impurities having the first conductivity type of the first region and the second region.

According to yet another embodiment of the present disclosure, there is provided a SPAD structure including: a substrate having a front surface and a rear surface; an isolation region disposed at a boundary of a unit pixel; a first impurity doped region disposed on the front surface of the substrate within the substrate; a second impurity doped region disposed on the first impurity doped region within the substrate; a first contact region disposed within the first impurity doped region; a second contact region disposed between the front surface of the substrate and the isolation region; and a guide wall surrounding side walls of the first impurity doped region and the second impurity doped region within the substrate, wherein the guide wall includes: a first region disposed on the second contact region within the substrate; and a second region that is disposed on and extends from a rear surface of the first region such that the second region is in contact with the side wall of the second impurity doped region adjacent to the second region.

According to yet another embodiment of the present disclosure, the first region of the SPAD structure according to the present disclosure may have impurities having a first conductivity type which has a lower concentration compared to a concentration of impurities having the first conductivity type of the second contact region and which has a higher concentration compared to a concentration of impurities having the first conductivity type of the second region.

According to yet another embodiment of the present disclosure, in the SPAD structure according to the present disclosure, the second contact region, the first region, and the second region may have a first conductivity type impurity doping concentration that gradually decreases from the second contact region to the first region and from the first region to the second region.

According to yet another embodiment of the present disclosure, the second region of the SPAD structure according to the present disclosure may have a rear surface disposed higher than a rear surface of the second impurity doped region, the side wall of which is in contact with the second region.

According to yet another embodiment of the present disclosure, the first region of the SPAD structure according to the present disclosure may be disposed apart from the side wall of the first impurity doped region adjacent to the first region.

According to yet another embodiment of the present disclosure, the guide wall of the SPAD structure according to the present disclosure may have an impurity doped region of an opposite type to the first impurity doped region.

According to yet another embodiment of the present disclosure, there is provided a SPAD structure including: a substrate having a front surface and a rear surface; a first impurity doped region disposed on the front surface of the substrate within the substrate; a guide wall including a first region disposed apart from the first impurity doped region within the substrate and a second region traversing a unit pixel, the second region being disposed on the first region; and a second impurity doped region disposed within the second region, wherein the second impurity doped region has impurities having a first conductivity type that has a lower concentration compared to a concentration of impurities having the first conductivity type of the second region.

According to yet another embodiment of the present disclosure, the second impurity doped region of the SPAD structure according to the present disclosure may be formed by injecting impurities having a second conductivity type in the second region after the second region is formed.

According to the above configurations, the present disclosure has the following effects.

In the present disclosure, the guide wall is formed on the side portions of the first impurity doped region and the second impurity doped region so as to induce photogenerated charges to be diffused to the avalanche region on the PN junction region between the first impurity doped region and the second impurity doped region, so that there is an effect that Photon Detection Efficiency (PDE) is increased.

In addition, in the present disclosure, a gap between the first region and the second region is not formed, so that there is an effect that photogenerated charges generated in the side portion of the substrate are prevented from being diffused to the side portion of the PN junction region.

In addition, in the present disclosure, the second region is doped with impurities having the low concentration compared to that of the first region, so that there is an effect that photogenerated charges generated in the side portion of the substrate are diffused to the avalanche region.

In addition, in the present disclosure, the guard ring is formed between the first region and both the first impurity doped region and the second impurity doped region, so that there is an effect that dark count rate is lowered.

In addition, in the present disclosure, the second region is formed such that the second region is in contact with the second impurity doped region, so that there is an effect that photogenerated charges are diffused to the avalanche region.

In addition, in the present disclosure, the second region that is the region doped with impurities having the first conductivity type overlaps the second impurity doped region that is the region doped with impurities having the first conductivity type that has the low concentration compared to that of the second region, so that there is an effect that the second impurity doped region is prevented from being misaligned with the first impurity doped region.

Meanwhile, though not explicitly mentioned, effects described in the present specification and tentative effects, expected from the technical features of the present specification will be treated as described in the present specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a conventional Single Photon Avalanche Diode (SPAD) pixel structure;

FIG. 2 is a cross-sectional view illustrating a SPAD structure according to a first embodiment of the present disclosure;

FIG. 3 is a cross-sectional view illustrating a SPAD structure according to a second embodiment of the present disclosure;

FIG. 4 is a cross-sectional view illustrating a SPAD structure according to a third embodiment of the present disclosure;

FIG. 5 is a cross-sectional view illustrating a SPAD structure according to a fourth embodiment of the present disclosure; and

FIG. 6 to FIG. 11 are cross-sectional views illustrating a manufacturing method of the SPAD structure according to an embodiment of the present disclosure.

### DETAILED DESCRIPTION OF THE EMBODIMENTS

Hereinafter, embodiments of the present disclosure will be described in detail with reference to accompanying drawings. Various changes to the following embodiments are possible and the scope of the present disclosure is not limited to the following embodiments. The patent right of the present disclosure should be defined by the scope and spirit of the present disclosure as disclosed in the accompanying claims. In addition, embodiments of the present disclosure are intended to fully describe the present disclosure to a person having ordinary knowledge in the art to which the present disclosure pertains.

As used in this specification, a singular form may include a plural form unless definitely indicating a particular case in terms of the context. Also, the expressions ‘comprise’ and/or ‘comprising’ used in this specification neither define the mentioned shapes, numbers, steps, operations, members, elements, and/or groups of these, nor exclude the presence or addition of one or more other different shapes, numbers, steps, operations, members, elements, and/or groups of these, or addition of these.

Hereinafter, when it is described that a component (or a layer) is referred to as being on another component (or another layer), it should be understood that the component is directly on the other component, or one or more intervening components (or layers) are also present. In contrast, when it is described that a component is referred to as being directly on to another component, it should be understood that there is (are) no intervening component(s) present. In addition, the terms indicating positions, such as, being located ‘on’, ‘upper’, ‘lower’, ‘upper side’, ‘lower side’, ‘first side’, and ‘side surface’ are intended to mean a relative position of the components.

In addition, the terms first, second, and so on may be used in order to describe various and/or multiple items, such as elements, regions, and/or portions, but the existence of a second element does not presuppose the existence of a first element.

In addition, conductivity types or doped regions of elements may be defined as ‘p-type’ or ‘n-type’ according to main carrier characteristics, but this is only for convenience of description, and the technical idea of the present disclosure is not limited thereto. For example, hereinafter, ‘p-type’ and ‘n-type’ may be referred to using the more general terms ‘first conductivity type’ and ‘second conductivity type’. Herein, ‘first conductivity type’ may refer to ‘p-type’, and ‘second conductivity type’ may refer to ‘n-type’.

In addition, it is to be understood that the terms ‘heavily’ and ‘lightly’ in reference to the doping concentration in an impurity region refer to relative doping concentrations of one impurity region relative to another impurity region.

Hereinafter, a Single Photon Avalanche Diode (SPAD) structure 1 according to the present disclosure will be described in detail with reference to the accompanying drawings. It is preferable that the SPAD structure 1 according to the present disclosure is a SPAD structure for a backside illuminated image sensor, but the scope of the present disclosure is not limited thereto.

The present disclosure relates to a SPAD structure. More particularly, the present disclosure relates to a SPAD structure configured such that a guide wall is formed on side portions of a first impurity doped region and a second impurity doped region so as to induce photogenerated charges to be diffused to an avalanche region A on a PN junction region between the first impurity doped region and the second impurity doped region, thereby increasing Photon Detection Efficiency (PDE).

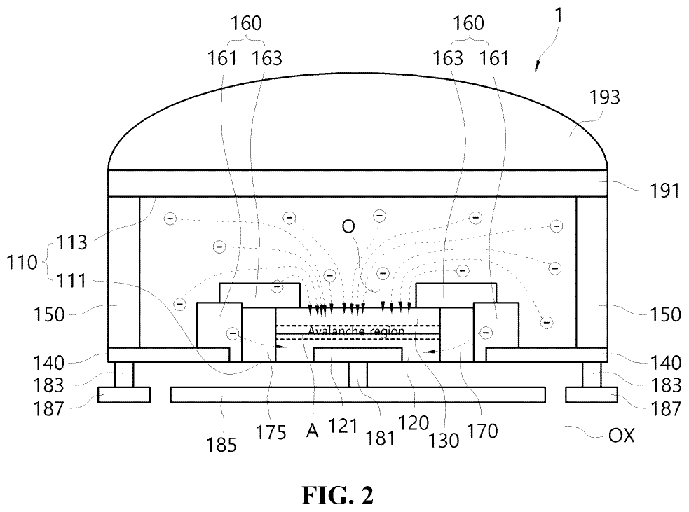

FIG. 2 is a cross-sectional view illustrating a SPAD structure according to a first embodiment of the present disclosure.

First, the SPAD structure 1 according to the first embodiment of the present disclosure will be described in detail.

Referring to FIG. 2, in the structure 1 according to the first embodiment of the present disclosure, a substrate 110 having a front surface 111 and a rear surface 113 is formed. Such a substrate 110 is a lightly doped impurity region having a first conductivity type, and may be formed by epitaxial growth.

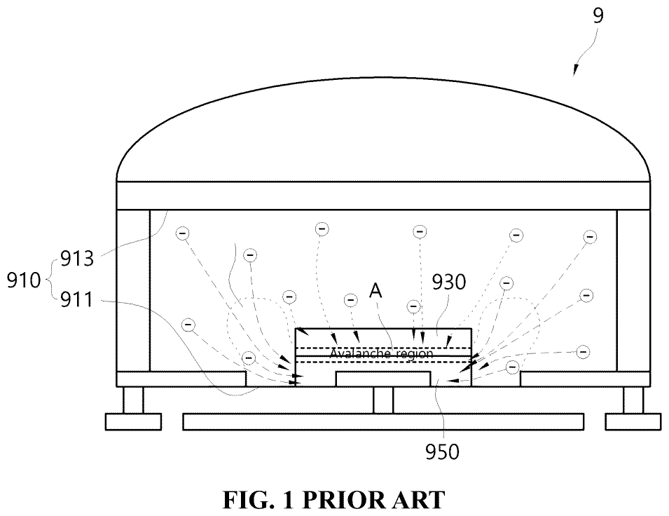

In addition, a first impurity doped region 120 may be formed on the front surface 111 of the substrate 110. The first impurity doped region 120 may be a lightly doped impurity region having a second conductivity type formed on a surface of the substrate 110. The first impurity doped region 120 and a second impurity doped region 130 above the first impurity doped region 120 form a PN junction region, and a region between the two regions 120 and 130 may be an avalanche region A that is an avalanche amplification region. The term ‘avalanche region A’ described above refers to a region having a high electric field in a depletion region (see FIG. 1), and may be formed on an interface of the first impurity doped region 120 and the second impurity doped region 130.

In addition, a first contact region 121 may be formed within the first impurity doped region 120. That is, the first contact region 121 may be formed such that the first contact region 121 is surrounded by the first impurity doped region 120. Such a first contact region 121 is an impurity doped region having the second conductivity type, and it is preferable that the first contact region 121 is an impurity doped region with a high concentration compared to that of the first impurity doped region 120. The first contact region 121 may be electrically or physically connected to a first metal contact region 181 on the front surface 111 of the substrate 110. The first contact region 121 may be formed on a surface of the front surface 111 of the substrate 110, but the scope of the present disclosure is not limited thereto. Such a first contact region 121 may be electrically connected to cathode electrodes 181 and 185.

In addition, the second impurity doped region 130 may be formed on the first impurity doped region 120 in the substrate 110. The PN junction region may be formed by the second impurity doped region 130 and the first impurity doped region 120. The second impurity doped region 130 is an impurity doped region having the first conductivity type, and it is preferable that the second impurity doped region 130 is doped with a high concentration of impurities compared to that of the substrate 110 and is doped with a low concentration of impurities compared to that of a guide wall 160 that will be described later.

In addition, a second contact region 140 may be formed on the front surface 111 of the substrate 110 by being spaced apart from the first impurity doped region 120. The second contact region 140 may be formed such that the second contact region 140 is spaced apart from the first impurity doped region 120 and surrounds a side portion of the first impurity doped region 120 by a predetermined height. That is, the second contact region 140 may be formed as a disk type for example, but the scope of the present disclosure is not limited thereto. In the illustrated cross-sectional view, the second contact region 140 may be formed such that the second contact region 140 is spaced apart from left and right sides of the first contact region 121. Such a second contact region 140 is an impurity doped region having the first conductivity type, and it is preferable that the second contact region 140 is doped with impurities having the first conductivity type that has a high concentration compared to that of the guide wall 160 that will be described later. In addition, the second contact region 140 may be electrically or physically connected to a second metal contact region 183 on the front surface 111 of the substrate 110. The second contact region 140 may be electrically connected to cathode electrodes 183 and 187.

In the following description, an isolation region 150 may be formed on a boundary of a unit pixel. As an example, the isolation region 150 may be formed such that the isolation region 150 extends in a vertical direction from the rear surface 113 of the substrate 110 to the second contact region 140 or to the front surface 111. For example, the isolation region 150 may be an impurity doped region having the first conductivity type.

In addition, the guide wall 160 having a side wall structure may be formed in the substrate 110, the guide wall 160 being spaced apart from side walls of the first impurity doped region 120 and the second impurity doped region 130. Such a guide wall 160 is an impurity doped region having the first conductivity type. The guide wall 160 is configured to prevent charges from being diffused to a side portion of the PN junction region between the first impurity doped region 120 and the second impurity doped region 130, and is configured to guide the charges to be moved to the avalanche region A. At this time, the guide wall 160 is required to be doped with impurities that is opposite type of the first impurity doped region 120. In addition, the guide wall 160 may include a first region 161 and a second region 163.

The first region 161 is an impurity doped region that extends from the front surface 111 of the substrate 110 toward the rear surface 113 by a predetermined depth. In addition, it is preferable that the first region 161 is doped with a high concentration of impurities compared to that of the second impurity doped region 130 and is doped with a low concentration of impurities compared to that of the second contact region 140.

By configuring the first region 161 in this manner, charges generated between the first region 161 and the isolation region 150 may be easily moved to the second region 163 that will be described later. In addition, an upper surface of the first region 161 may extend to a position higher than an upper surface of the second impurity doped region 130 (or a position adjacent to the rear surface 113 of the substrate 110), or may extend by a height same as a height of the upper surface of the second impurity doped region 130. The first region 161 may be formed in a ring type that surrounds the side walls of the first impurity doped region 120 and the second impurity doped region 130, but the scope of the present disclosure is not limited thereto. At this time, it is preferable that the first region 161 is formed such that the first region 161 is spaced apart from the adjacent first impurity doped region 120 and the second impurity doped region 130 in a lateral direction.

The second region 163 is configured such that the second region 163 extends inwardly from the first region 161 in the substrate 110 (or toward the upper surface of the second impurity doped region 130) by a predetermined length. In the second region 163, a first side of a lower surface of the second region 163 may be in contact with an upper side of the second impurity doped region 130 or may be spaced apart from the upper side of the second impurity doped region 130 by a predetermined length, but it is preferable that the first side of the lower surface of the second region 163 is in contact with the upper side of the second impurity doped region 130. In addition, it is preferable that the second region 163 is formed as a ring type, for example, so that the upper surface of the second impurity doped region 130 has an opening O that is open in the substrate 110. Diffusion of electric charges to the avalanche region A may be guided through the opening O.

In addition, it is preferable that the second region 163 is a region doped with a low concentration of impurities having the first conductivity type compared to that of the first region 161. Therefore, electric charges generated between the guide wall 160 and the adjacent isolation region 150 may be easily moved to the opening O. In more detail, it is preferable that the first conductivity type impurity doping concentrations are gradually reduced toward the second impurity doped region 130, the first region 161, and the second region 163. Alternatively, the first region 161 and the second region 163 may have substantially the same first impurity doping concentration. In addition, it is preferable that the second region 163 and the adjacent first region 161 are physically connected to each other, but the scope of the present disclosure is not limited thereto.

In addition, a guard ring 170 may be formed between the first region 161 and both the adjacent first impurity doped region 120 and the adjacent second impurity doped region 130. The guard ring 170 is configured to lower a Dark Count Rate (DCR), and it is preferable that the guard ring 170 has a first impurity doping concentration substantially the same as the substrate 110.

For example, an insulation film layer OX such as an oxide film layer is formed on the front surface 111 of the substrate 110, and a first metal contact region 181 connected to the first contact region 121 and a first metal wiring 185 that is electrically or physically connected to the first metal contact region 181 may be formed in the insulation film layer OX. For example, the first metal wiring 185 is a metal layer formed of such as aluminum Al, and may function as a reflecting plate that reflects light incident from the rear surface 113 of the substrate 110, thereby forming a light path. In addition, in the insulation film layer OX, a second metal contact region 183 connected to the second contact region 140 and a second metal wiring 187 that is electrically or physically connected to the second metal contact region 183 may be formed.

In addition, a planarization layer 191 may be formed on the rear surface 113 of the substrate 110, and a micro lens 193 may be formed on the planarization layer 191.

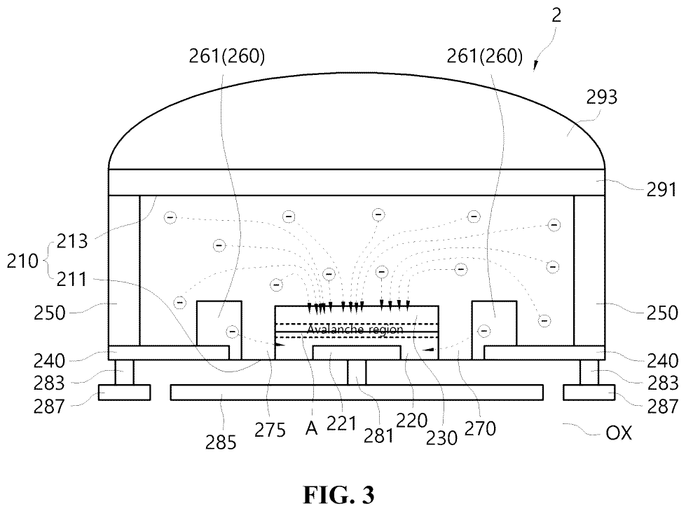

FIG. 3 is a cross-sectional view illustrating a SPAD structure according to a second embodiment of the present disclosure.

Hereinafter, a SPAD structure 2 according to the second embodiment of the present disclosure will be described in detail. Since the SPAD structure 2 hereinafter may be formed substantially the same as the SPAD structure 1 according to the first embodiment except for a guide wall 260, only the guide wall 260 will be described in detail. In addition, for the same configuration as the first embodiment, the first digit of the reference numeral in the first embodiment is changed from ‘1’ to ‘2’ in the second embodiment.

Referring to FIG. 3, in the SPAD structure 2 according to the second embodiment, the second region 163 according to the first embodiment is not formed. That is, in the second embodiment, the guide wall 260 includes only a first region 261. Such a first region 261 extends by a predetermined depth from a front surface 211 of the substrate 210 toward a rear surface 213 within a substrate 210. At this time, it is preferable that an upper surface of the first region 261 may extend to a position higher than an upper surface of an adjacent second impurity doped region 230 (or a position adjacent to the rear surface 213 of the substrate 210). By such a configuration, for example, charges generated between the guide wall 260 and an isolation region 250 may be maximally prevented from being moved to a side portion of a PN junction region formed by a first impurity doped region 220 and the second impurity doped region 230.

It is preferable that the described guide wall 260 is a region doped with high concentration first impurities compared to that of the second impurity doped region 230, and it is more preferable that the impurity doping concentration of the guide wall 260 is gradually reduced as the second impurity doped region 230 extends upward, but there is no additional limitation. In addition, it is preferable that the first region 261 is a region doped with low concentration second impurities compared to that of the second contact region 240.

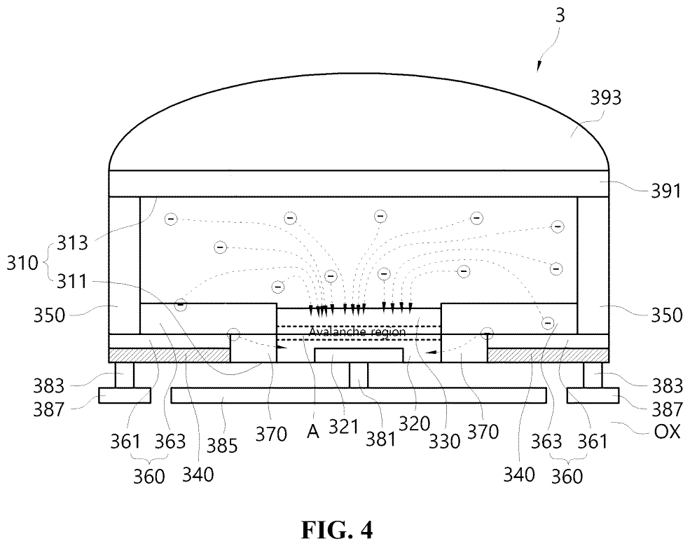

FIG. 4 is a cross-sectional view illustrating a SPAD structure according to a third embodiment of the present disclosure.

Hereinafter, a SPAD structure 3 according to the third embodiment of the present disclosure will be described in detail. Since the SPAD structure 3 hereinafter may be formed substantially the same as the SPAD structure 1 according to the first embodiment except for a guide wall 360, only the guide wall 360 will be described in detail. In addition, for the same configuration as the first embodiment, the first digit of the reference numeral in the first embodiment is changed from ‘1’ to ‘3’ in the third embodiment.

Referring to FIG. 4, in the SPAD structure 3 according to the third embodiment, the guide wall 360 may include a first region 361 and a second region 363. The first region 361 is an impurity doped region having the first conductivity type, and may be in contact with an adjacent isolation region 350, or may be spaced apart from the isolation region 350, such as the first region 161 according to the first embodiment. In addition, the second region 363 may be formed such that the second region 363 on the first region 361 is in contact with a side portion of an adjacent second impurity doped region 330. At this time, in a substrate 310, an upper surface of the first region 361 may have substantially the same height as an upper surface of the second impurity doped region 330, or may be formed at a higher position. In addition, it is preferable that the first conductivity type impurity doping concentrations are reduced toward a second contact region 340, the first region 361, and the second region 363, and it is more preferable that the first conductivity type impurity doping concentrations are gradually reduced.

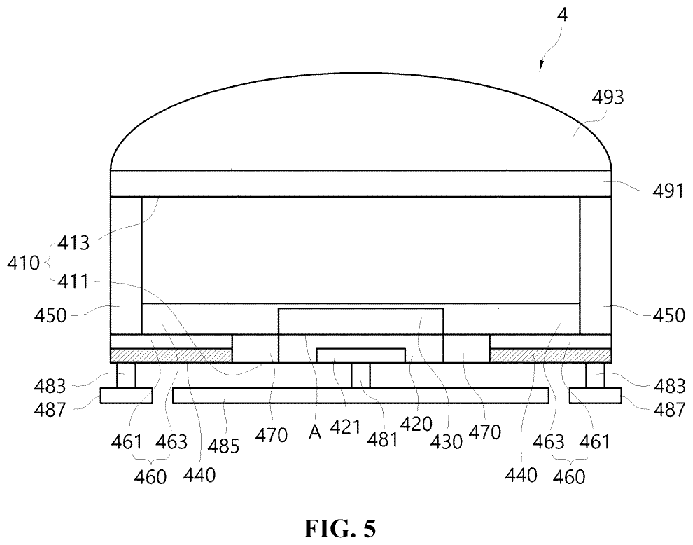

FIG. 5 is a cross-sectional view illustrating a SPAD structure according to a fourth embodiment of the present disclosure.

Hereinafter, a SPAD structure 4 according to the fourth embodiment of the present disclosure will be described in detail. Since the SPAD structure 4 hereinafter may be formed substantially the same as the SPAD structure 3 according to the third embodiment except for a second region 463 of a guide wall 460, only the guide wall 460 will be described in detail. In addition, for the same configuration as the third embodiment, the first digit of the reference numeral in the third embodiment is changed from ‘3’ to ‘4’ in the fourth embodiment.

Referring to FIG. 5, in the SPAD structure 4 according to the fourth embodiment, a second impurity doped region 430 is formed inside the second region 463. That is, the second region 463 does not have a ring type or a disk type, but has a continuous shape that does not have the opening O. For example, the second region 463 may be formed such that the second region 463 has a continuous shape in contact with a pair of isolation regions 450. Therefore, the second region 463 is formed so as to surround the second impurity doped region 430. That is, the second impurity doped region 430 may be formed in the second region 463 by doping the second impurity doped region 430 with first impurities with a low concentration compared to that of the second region 463. By forming the second impurity doped region 430 in this manner, misalignment between a first impurity doped region 420 and the second impurity doped region 430 positioned above the first impurity doped region 420 may be prevented.

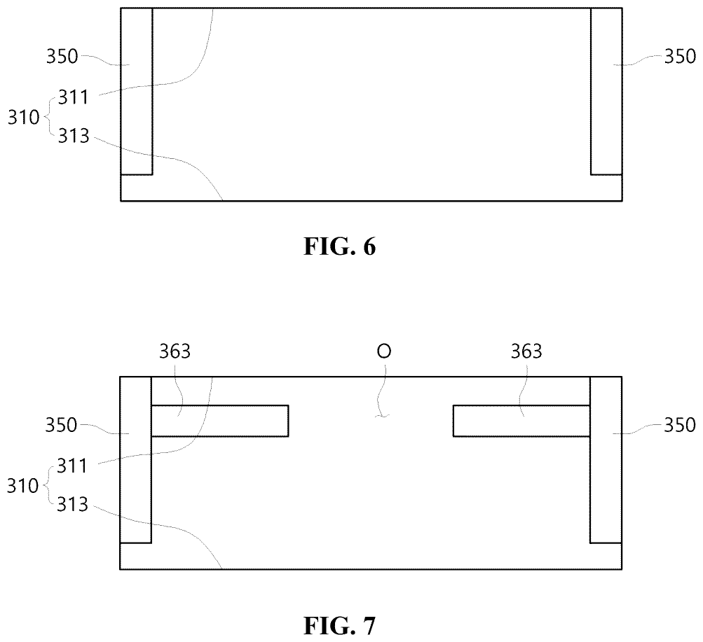

FIG. 6 to FIG. 11 are cross-sectional views illustrating a manufacturing method of the SPAD structure according to an embodiment of the present disclosure.

Hereinafter, a manufacturing method of the SPAD structure according to an embodiment of the present disclosure will be described in detail with reference to the accompanying drawings. The manufacturing method of the SPAD structure described above will be described in an exemplary manner on the basis of a manufacturing method of the SPAD structure according to the third embodiment of the present disclosure.

First, referring to FIG. 6, the isolation region 350 is formed in the substrate 310. Such an isolation region 350 may be formed by performing a first impurity ion implantation process after a mask pattern (not illustrated) is formed on a front surface 311 of the substrate 310. The isolation region 350 may be formed such that the isolation region 350 extends from the front surface 311 of the substrate 310 toward a rear surface 313 by a predetermined depth.

Then, referring to FIG. 7, the second region 363 in the substrate 310 is formed in a unit pixel divided by the isolation region 350. The second region 363 is a lightly doped first impurity region, and may be formed by performing an ion implantation process after a mask pattern (not illustrated) is formed on the b front surface 311 of the substrate 310. The second region 363 may be formed in a ring type or a disk type such that the opening O is formed.

At this time, as in the SPAD pixel structure 4 of the fourth embodiment, the second region 363 may be continuously formed such that the opening O is not formed.

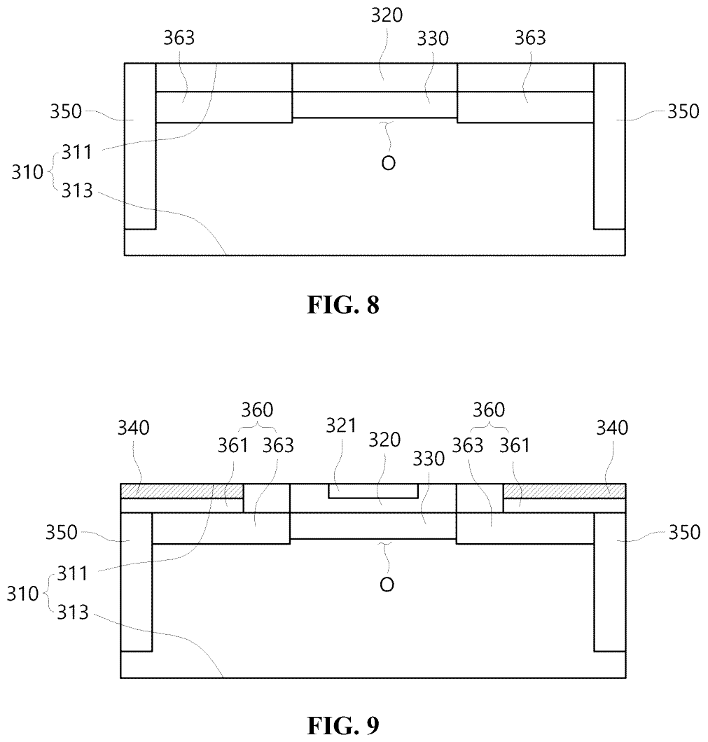

Then, referring to FIG. 8, the second impurity doped region 330 may be formed inside the second region 363 in the substrate 310, and then a first impurity doped region 320 may be formed on the front surface 311 of the substrate 310. It is preferable that the second impurity doped region 330 is a region doped with first impurities having a low concentration compared to that of the second region 363, and it is preferable that the first impurity doped region 320 is a region doped with second impurities having a lower concentration. At this time, a lower surface of the second impurity doped region 330 may be positioned adjacent to the front surface 311 in the substrate 310 than a lower surface of the second region 363, or may be formed at substantially the same depth/height. The second impurity doped region 330 and the first impurity doped region 320 may be formed by respectively performing the ion implantation process after a mask pattern (not illustrated) is formed on the front surface 311 of the substrate 310.

In addition, as in the SPAD pixel structure 4 of the fourth embodiment, when the second region 363 is continuously formed such that the opening O is not formed, the second impurity doped region 330 doped with impurities having the first conductivity type that has a low concentration compared to that of the second region 363 may be formed by doping second impurity ions in the second region 363.

Then, referring to FIG. 9, a first contact region 321 is formed in the first impurity doped region 320, and the first region 361 and the second contact region 340 are formed between the front surface 311 of the substrate 310 and the isolation region 350. Each region may be formed through the ion implantation process by utilizing a mask pattern (not illustrated) formed on the front surface 311 of the substrate 310.

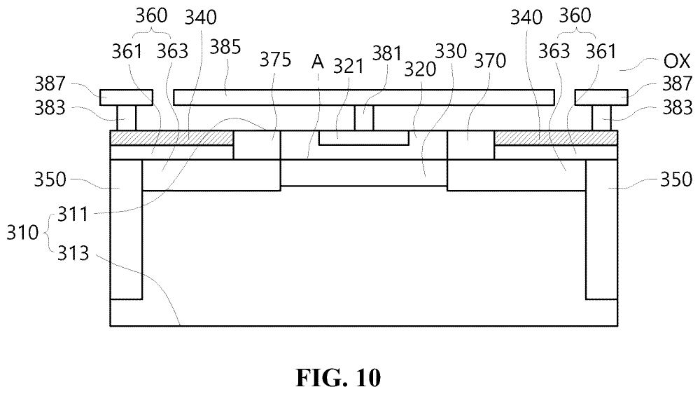

Then, referring to FIG. 10, the insulation film layer OX, metal contact regions 381 and 385, and metal wirings 383 and 387 are formed on the front surface 311 of the substrate 310.

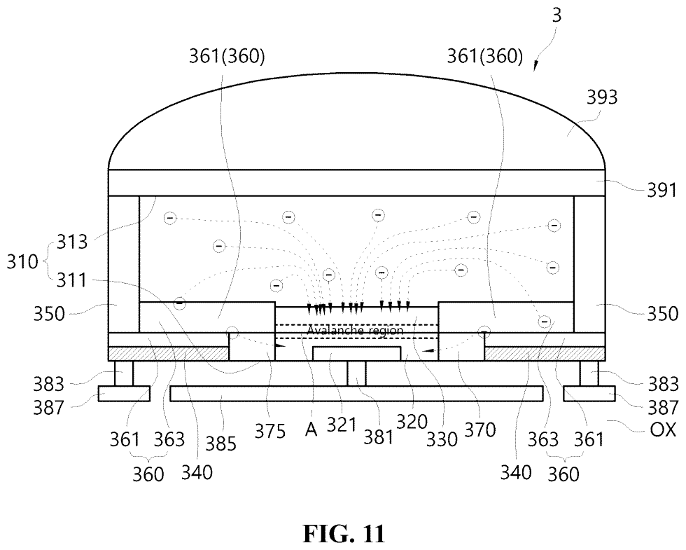

Referring to FIG. 11, a planarization layer 391 and a micro lens 393 are formed on the rear surface 313 after grinding the rear surface 313 of the substrate 310 as a subsequent process.

The foregoing detailed description is for illustrative purposes only. Furthermore, the description provides an embodiment of the present disclosure and the present disclosure may be used in other various combination, changes, and environments. That is, the present disclosure may be changed or modified within the scope of the present disclosure described herein, a range equivalent to the description, and/or within the knowledge or technology in the related art. The embodiments show an optimum state for achieving the spirit of the present disclosure, and various modification required for specific applications and uses of the present disclosure are also possible. Therefore, the detailed description of the present disclosure is not intended to limit the present disclosure in the embodiment.

What is claimed is:

1. A Single Photon Avalanche Diode (SPAD) structure comprising:
a substrate having a front surface and a rear surface;
a first impurity doped region disposed on the front surface of the substrate within the substrate;
a second impurity doped region disposed on the first impurity doped region within the substrate; and
a guide wall surrounding side walls of the first impurity doped region and the second impurity doped region within the substrate.

2. The SPAD structure of claim 1, wherein the guide wall has an impurity doped region having a first conductivity type, and the first impurity doped region has an impurity doped region having a second conductivity type.

3. The SPAD structure of claim 2, wherein the guide wall comprises a first region that extends from the front surface of the substrate toward the rear surface of the substrate.

4. The SPAD structure of claim 3, wherein, within the substrate, the first region has a rear surface disposed higher than a rear surface of the second impurity doped region.

5. The SPAD structure of claim 3, wherein the guide wall further comprises a second region that extends from a rear surface of the first region toward a rear surface of the second impurity doped region adjacent to the second region.

6. The SPAD structure of claim 5, wherein the second region is in contact with the second impurity doped region.

7. The SPAD structure of claim 5, wherein the second region has an opening so that the rear surface of the second impurity doped region is at least partially open.

8. The SPAD structure of claim 5, wherein the second region has impurities having the first conductivity type that has a lower concentration compared to a concentration of impurities having the first conductivity type of the first region.

9. The SPAD structure of claim 2, further comprising:
a first contact region disposed within the first impurity doped region on the front surface of the substrate; and
a second contact region disposed apart from the first contact region on the front surface of the substrate within the substrate.

10. The SPAD structure of claim 5, further comprising:
a guard ring disposed between the guide wall and both the first impurity doped region and the second impurity doped region that are adjacent to the guide wall.

11. The SPAD structure of claim 10, wherein the guard ring has impurities having the first conductivity type that has a lower concentration compared to concentrations of impurities having the first conductivity type of the first region and the second region.

12. A SPAD structure comprising:
a substrate having a front surface and a rear surface;
an isolation region disposed at a boundary of a unit pixel;
a first impurity doped region disposed on the front surface of the substrate within the substrate;
a second impurity doped region disposed on the first impurity doped region within the substrate;
a first contact region disposed within the first impurity doped region;
a second contact region disposed between the front surface of the substrate and the isolation region; and
a guide wall surrounding side walls of the first impurity doped region and the second impurity doped region within the substrate,
wherein the guide wall comprises:
a first region disposed on the second contact region within the substrate; and
a second region that is disposed on and extends from a rear surface of the first region such that the second region is in contact with the side wall of the second impurity doped region adjacent to the second region.

13. The SPAD structure of claim 12, wherein the first region has impurities having a first conductivity type which has a lower concentration compared to a concentration of impurities having the first conductivity type of the second contact region and which has a higher concentration compared to a concentration of impurities having the first conductivity type of the second region.

14. The SPAD structure of claim 12, wherein the second contact region, the first region, and the second region have a first conductivity type impurity doping concentration that gradually decreases from the second contact region to the first region and from the first region to the second region.

15. The SPAD structure of claim 12, wherein, the second region has a rear surface disposed higher than a rear surface of the second impurity doped region, the side wall of which is in contact with the second region.

16. The SPAD structure of claim 12, wherein the first region is disposed apart from the side wall of the first impurity doped region adjacent to the first region.

17. The SPAD structure of claim 12, wherein the guide wall has an impurity doped region of an opposite type to the first impurity doped region.

18. A SPAD structure comprising:
a substrate having a front surface and a rear surface;
a first impurity doped region disposed on the front surface of the substrate within the substrate;
a guide wall comprising a first region disposed apart from the first impurity doped region within the substrate and a second region traversing a unit pixel, the second region being disposed on the first region; and
a second impurity doped region disposed within the second region,
wherein the second impurity doped region has impurities having a first conductivity type that has a lower concentration compared to a concentration of impurities having the first conductivity type of the second region.

19. The SPAD structure of claim 18, wherein the second impurity doped region is formed by injecting impurities having a second conductivity type in the second region after the second region is formed.
